(19) United States
(12) Patent Application Publication
(10) Pub. No.: US 2024/0321599 A1
(43) Pub. Date: Sep. 26, 2024

(54) CHEMICAL SUPPLY APPARATUS, SEMICONDUCTOR FABRICATION SYSTEM INCLUDING THE SAME, AND SUBSTRATE PROCESSING METHOD USING THE SAME

(71) Applicant: Samsung Electronics Co., Ltd., Suwon-si (KR)

(72) Inventors: Hoyoung RYU, Suwon-si (KR); SEUNGKWAN HONG, Seoul (KR); JAEWON LEE, Seoul (KR); Daeok KIM, Suwon-si (KR); YEOJIN SHIN, Seoul (KR); Dongchan CHOI, Suwon-si (KR)

(73) Assignees: Samsung Electronics Co., Ltd., Suwon-si (KR); KOREA UNIVERSITY Research and Business Foundation, Seoul (KR)

(21) Appl. No.: 18/418,827

(22) Filed: Jan. 22, 2024

(30) Foreign Application Priority Data
Mar. 22, 2023 (KR) 10-2023-0037500
Jun. 29, 2023 (KR) 10-2023-0084011

(51) Int. Cl. H01L 21/67; B01J 35/39; H01L 21/02

(52) U.S. Cl. CPC H01L 21/67051; B01J 35/39; H01L 21/02052; H01L 21/67115

(57) ABSTRACT

Disclosed are semiconductor fabrication systems, chemical supply apparatuses, and substrate processing methods. The semiconductor fabrication system comprises a substrate processing apparatus and a chemical supply apparatus that supplies the substrate processing apparatus with a chemical. The chemical supply apparatus includes a main tank, a supply line that connects the main tank to an inlet of the substrate processing apparatus, a recycle tank connected to an outlet of the substrate processing apparatus, and a recycle filtering device between the recycle tank and the main tank. The recycle filtering device includes a photocatalytic reactor, a nanofilter between the photocatalytic reactor and the main tank, and a connection line that connects the photocatalytic reactor to the nanofilter.

### CROSS-REFERENCE TO RELATED APPLICATIONS

This U.S. nonprovisional application claims priority under 35 U.S.C § 119 to Korean Patent Applications No. 10-2023-0037500 filed on Mar. 22, 2023, and No. 10-2023-0084011 filed on Jun. 29, 2023, in the Korean Intellectual Property Office, the disclosures of which are hereby incorporated by reference in their entirety.

### BACKGROUND

The present inventive concepts relate to a chemical supply apparatus, a semiconductor fabrication system including the same, and a substrate processing method using the same, and more particularly, to a chemical supply apparatus capable of reusing chemicals, a semiconductor fabrication system including the same, and a semiconductor fabrication method using the same.

A semiconductor device may be fabricated by using various processes. For example, a semiconductor device may be manufactured by allowing a silicon wafer to undergo a photolithography process, an etching process, a deposition process, and so forth. Various chemicals may be used in these processes. For example, diluted sulfuric peroxide (DSP) may be used to treat a substrate. A chemical supply apparatus may be utilized to supply the diluted sulfuric peroxide (DSP) to a substrate processing apparatus.

### SUMMARY

Some embodiments of the present inventive concepts provide a chemical supply apparatus capable of reusing chemicals, a semiconductor fabrication system including the same, and a substrate processing method using the same.

Some embodiments of the present inventive concepts provide a chemical supply apparatus capable of reducing discharge of waste water, a semiconductor fabrication system including the same, and a substrate processing method using the same.

Some embodiments of the present inventive concepts provide a chemical supply apparatus capable of preventing damage to a nanofiltration membrane, a semiconductor fabrication system including the same, and a substrate processing method using the same.

The object of the present inventive concepts is not limited to the mentioned above, and other objects which have not been mentioned above will be clearly understood to those skilled in the art from the following description.

According to some embodiments of the present inventive concepts, a semiconductor fabrication system may comprise: a substrate processing apparatus; and a chemical supply apparatus that supplies the substrate processing apparatus with a chemical. The chemical supply apparatus may include: a main tank; a supply line that connects the main tank to an inlet of the substrate processing apparatus; a recycle tank connected to an outlet of the substrate processing apparatus; and a recycle filtering device between the recycle tank and the main tank. The recycle filtering device may include: a photocatalytic reactor; a nanofilter between the photocatalytic reactor and the main tank; and a connection line that connects the photocatalytic reactor to the nanofilter.

According to some embodiments of the present inventive concepts, a chemical supply apparatus may comprise: a main tank that temporarily stores fluid; a supply line connected to the main tank to allow a substrate processing apparatus to receive the fluid stored in the main tank; a recycle line connected to the main tank to allow the main tank to receive the fluid discharged from the substrate processing apparatus; a recycle tank on the recycle line; and a recycle filtering device between the recycle tank and the main tank. The recycle filtering device may include: a photocatalytic reactor that has an ultraviolet (UV) lamp; a nanofilter between the photocatalytic reactor and the main tank; a connection line that connects the photocatalytic reactor to the nanofilter; and a concentrated water collection line that connects the nanofilter to the photocatalytic reactor. The concentrated water collection line may be in parallel with the connection line.

According to some embodiments of the present inventive concepts, a substrate processing method may comprise: placing a substrate in a substrate processing apparatus; allowing a chemical supply apparatus to supply a chemical to the substrate processing apparatus in which the substrate is placed; and filtering fluid discharged from the substrate processing apparatus. The chemical supply apparatus may include: a main tank; a supply line that connects the main tank to an inlet of the substrate processing apparatus; and a recycle filtering device connected to an outlet of the substrate processing apparatus. The recycle filtering device may include: a photocatalytic reactor; and a nanofilter connected to the photocatalytic reactor. The step of filtering the fluid may include: allowing the fluid discharged from the substrate processing apparatus to pass through the photocatalytic reactor; and allowing the fluid released from the photocatalytic reactor to pass through the nanofilter.

Details of other example embodiments are included in the description and drawings.

### BRIEF DESCRIPTION OF DRAWINGS

FIG. 1 illustrates a simplified schematic diagram showing a semiconductor fabrication system according to some embodiments of the present inventive concepts.

FIG. 2 illustrates a simplified schematic diagram showing a recycle filtering device according to some embodiments of the present inventive concepts.

FIG. 3 illustrates a cross-sectional view showing a photocatalytic reactor of a recycle filtering device according to some embodiments of the present inventive concepts.

FIG. 4 illustrates a cross-sectional view showing a nanofilter of a recycle filtering device according to some embodiments of the present inventive concepts.

FIG. 5 illustrates a cross-sectional view showing a substrate processing apparatus according to some embodiments of the present inventive concepts.

FIG. 6 illustrates a flow chart showing a substrate processing method according to some embodiments of the present inventive concepts.

FIGS. 7 to 13 illustrate cross-sectional views showing a substrate processing method according to the flow chart of FIG. 6.

FIG. 14 illustrates a simplified schematic diagram showing a substrate fabrication system according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

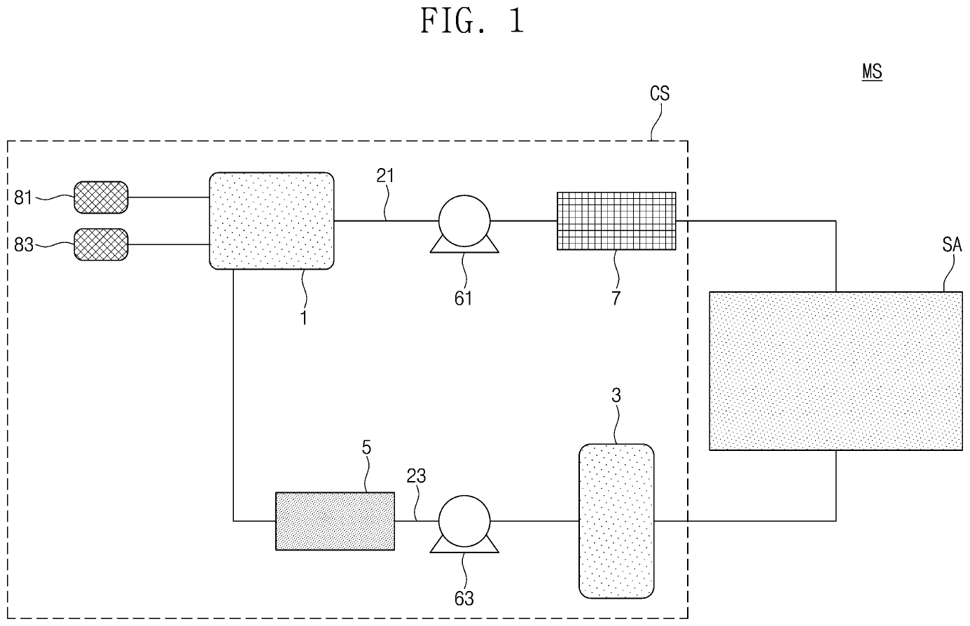

FIG. 1 illustrates a simplified schematic diagram showing a semiconductor fabrication system according to some embodiments of the present inventive concepts.

Referring to FIG. 1, a semiconductor fabrication system MS may be provided. The semiconductor fabrication system MS may be a system to manufacture a semiconductor device. For example, the semiconductor fabrication system MS may be configured to allow a substrate to undergo one or more of a deposition process, an etching process, and a cleaning process. The substrate may be a silicon (Si) wafer, but the present inventive concepts are not limited thereto (e.g. another type of semiconductor wafer (e.g. Ge) or a glass, quartz, etc. wafer could be used. The semiconductor fabrication system MS may include a substrate processing apparatus SA and a chemical supply apparatus CS.

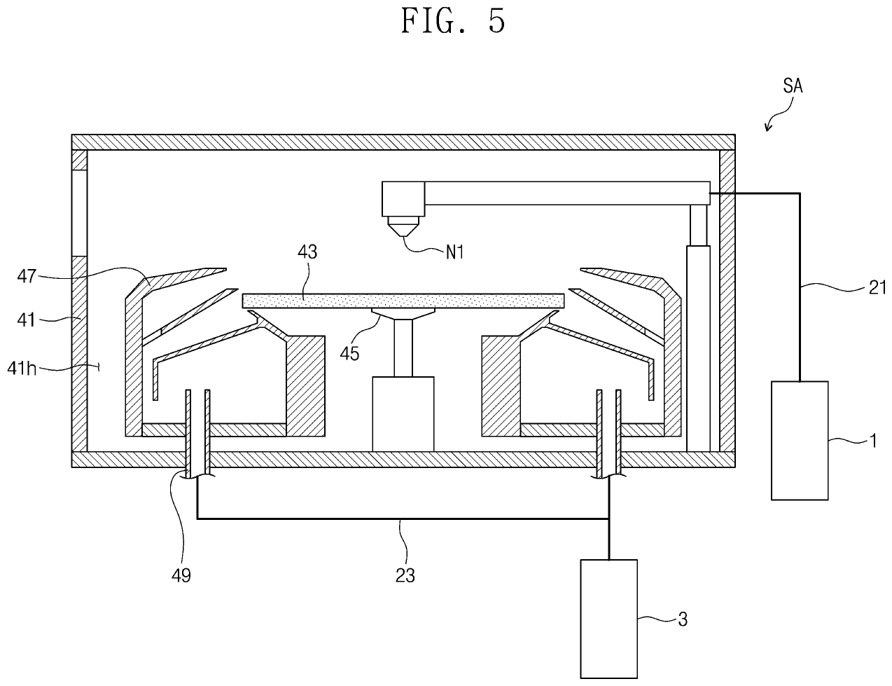

The substrate processing apparatus SA may perform a process on a substrate. For example, the substrate processing apparatus SA may allow the substrate to undergo one or more of a deposition process, an etching process, and a cleaning process. The substrate processing apparatus SA may include one or more of a substrate deposition chamber, a substrate etching chamber, and a substrate cleaning chamber. The substrate processing apparatus SA may use fluid to treat the substrate. For example, the substrate processing apparatus SA may use chemicals to treat the substrate. The substrate processing apparatus SA may be connected to the chemical supply apparatus CS. The substrate processing apparatus SA will be further discussed in detail with reference to FIG. 5.

The chemical supply apparatus CS may supply the substrate processing apparatus SA with chemicals. The chemical supply apparatus CS may be connected to the substrate processing apparatus SA. For example, the chemical supply apparatus CS may be connected to an inlet of the substrate processing apparatus SA. When the substrate processing apparatus SA includes a substrate cleaning chamber, the inlet of the substrate processing apparatus SA may be a cleaning nozzle (see N1 of FIG. 5). The chemical supply apparatus CS may supply the substrate processing apparatus SA with various kinds of chemical. For example, the chemical supply apparatus CS may supply the substrate processing apparatus SA with diluted sulfuric peroxide (DSP). DSP is a mixture of sulfuric acid, hydrogen peroxide and water. As such, sulfuric acid (H₂SO₄) may be included in fluid that is supplied to the substrate processing apparatus SA from the chemical supply apparatus CS. Alternatively, hydrochloric acid/hydrogen peroxide/water may be provided, hydrofluoric acid/hydrogen peroxide/water, or a combination of acids can be used, e.g. HF/HCl/H₂O₂/H₂O, or H₂SO₄/HF/H₂O₂/H₂O, H₂SO₄/HCl/H₂O₂/H₂O, or a base fluid can be provided e.g. ammonium hydroxide/hydrogen peroxide/water, where the above combinations may have additional components (e.g. a surfactant, etc.). The chemical supply apparatus CS may reuse a portion of fluid discharged from the substrate processing apparatus SA. The chemical supply apparatus CS may be connected to an outlet (see 49 of FIG. 5) of the substrate processing apparatus SA. To reuse fluid discharged from the substrate processing apparatus SA, the chemical supply apparatus CS may filter the fluid discharged from the substrate processing apparatus SA. The chemical supply apparatus CS may include a main tank 1, a supply line 21, a first filtering device 7, a main pump 61, a recycle tank 3, a recycle line 23, a recycle filtering device 5, a recycle pump 63, a first supply device 81, and a second supply device 83.

The main tank 1 may temporarily store fluid. For example, the main tank 1 may temporarily fluid supplied from one or more of the first supply device 81 and the second supply device 83. The main tank 1 may supply the substrate processing apparatus SA with the fluid stored in the main tank 1.

The supply line 21 may connect the main tank 1 to the substrate processing apparatus SA. The fluid stored in the main tank 1 may be supplied through the supply line 21 to the substrate processing apparatus SA.

The first filtering device 7 may be positioned on the supply line 21. For example, the first filtering device 7 may be positioned between the main tank 1 and the substrate processing apparatus SA. The first filtering device 7 may filter foreign substances in the fluid that is supplied from the main tank 1 to the substrate processing apparatus SA. The first filtering device 7 may include an ultrafiltration membrane, but the present inventive concepts are not limited thereto.

The main pump 61 may be positioned on the supply line 21. For example, the main pump 61 may be positioned between the main tank 1 and the substrate processing apparatus SA. The main pump 61 may cause the fluid to move from the main tank 1 to the substrate processing apparatus SA.

The recycle tank 3 may be connected to the substrate processing apparatus SA. The recycle tank 3 may temporarily store the fluid discharged from the substrate processing apparatus SA. For example, the recycle tank 3 may be connected to the outlet (see 49 of FIG. 5) of the substrate processing apparatus SA.

The recycle line 23 may connect the substrate processing apparatus SA to the recycle tank 3. In addition, the recycle line 23 may connect the recycle tank 3 to the main tank 1. The fluid discharged from the substrate processing apparatus SA may move along the recycle line 23 through the recycle tank 3, and may then enter the main tank 1.

The recycle filtering device 5 may be connected to the recycle tank 3. The recycle filtering device 5 may be positioned on the recycle line 23. For example, the recycle filtering device 5 may be positioned between the recycle tank 3 and the main tank 1. The fluid discharged from the substrate processing apparatus SA may be filtered while passing through the recycle filtering device 5. The fluid filtered in the recycle filtering device 5 may be introduced into the main tank 1. For example, the recycle filtering device 5 may eliminate foreign substances from the fluid discharged from the substrate processing apparatus SA. The recycle filtering device 5 will be further discussed in detail below.

The recycle pump 63 may be positioned on the recycle line 23. For example, the recycle pump 63 may be positioned between the recycle tank 3 and the recycle filtering device 5. The recycle pump 63 may cause the recycle filtering device 5 to receive the fluid stored in the recycle pump 63.

The first supply device 81 may supply the main tank 1 with a first fluid. For example, the first supply device 81 may supply the main tank 1 with deionized water (DIW). The first fluid may be deionized water (DIW).

The second supply device 83 may supply the main tank 1 with a second fluid. The second fluid may be different from the first fluid. For example, the second supply device 83 may supply the main tank 1 with diluted sulfuric peroxide (DSP). The second fluid may be diluted sulfuric peroxide (DSP).

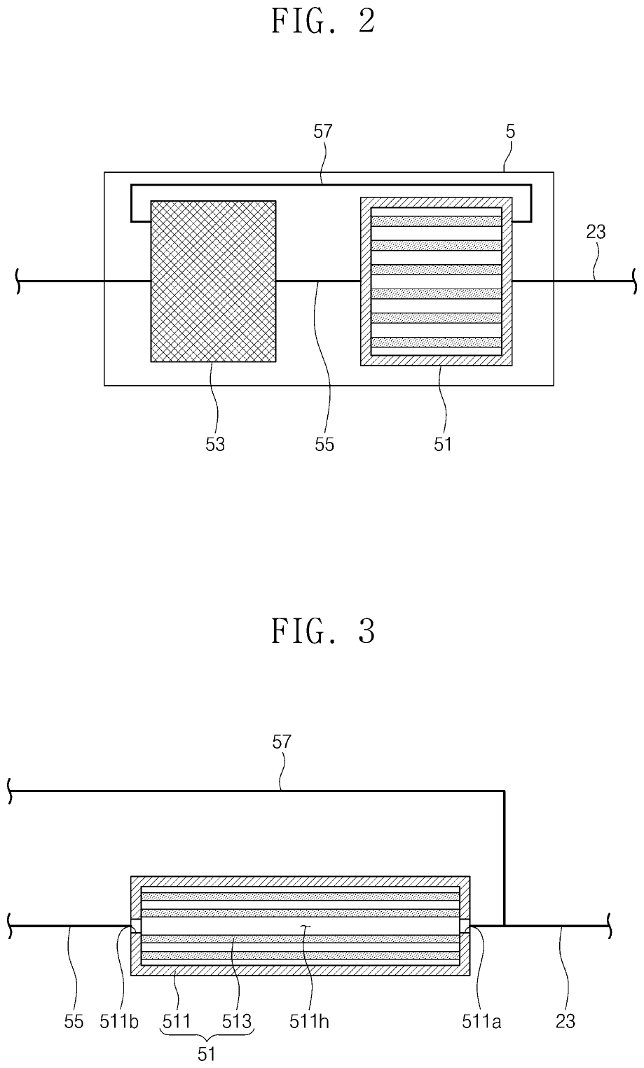

FIG. 2 illustrates a simplified schematic diagram showing a recycle filtering device according to some embodiments of the present inventive concepts.

Referring to FIG. 2, the recycle filtering device 5 may include a photocatalytic reactor 51, a nanofilter 53, a connection line 55, and a concentrated water collection line 57.

The photocatalytic reactor 51 may irradiate ultraviolet (UV) light to the fluid. The photocatalytic reactor 51 may induce a photocatalytic reaction in the fluid. Thus, hydrogen peroxide (H₂O₂) in the fluid may be decomposed. In addition, an organic substance in the fluid may be decomposed in the photocatalytic reactor 51. The photocatalytic reactor 51 will be further discussed in detail below with reference to FIG. 3.

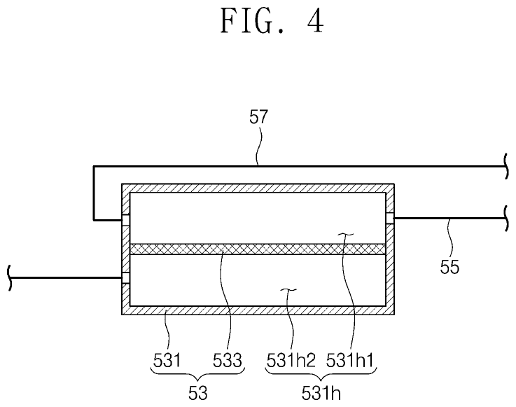

The nanofilter 53 may be positioned between the photocatalytic reactor 51 and the main tank (see 1 of FIG. 1). A fluid that has passed through the photocatalytic reactor 51 may be introduced into the nanofilter 53. The nanofilter 53 may filter foreign substances in the fluid. A combination of filters may be used such as multiple nanofilters in series or parallel. Or a combination of different types of filters may be used, such as where the fluid passes first through an ultrafiltration filter followed by a nanofiltration filter. In one example, the nanofilter has a pore size of 0.2 to 10 nm (e.g. from 1 to 5 nm). If another type of filter is also used, for example an ultrafiltration filter can have a pore size of e.g. from 0.005 to 0.1 μm. The nanofiltration membrane can be made of a polymeric material (e.g. cellulose acetate, polyamide, polyetherimides (PEI), polyimide (PI), polysulfone (PS), or poly (ether) sulfone (PES), or a hybrid organic-inorganic material (e.g. a polymer-silica composite, a silicone/siloxane based membrane, etc.). The nanofilter 53 will be further discussed in detail below with reference to FIG. 4.

The connection line 55 may connect the photocatalytic reactor 51 to the nanofilter 53. The connection line 55 may be a portion of the recycle line 23. Alternatively, the connection line 55 may be a pipe separately inserted in the middle of the recycle line 23. The fluid that has passed through the photocatalytic reactor 51 may move along the connection line 55 to the nanofilter 53.

The concentrated water collection line 57 may connect a rear end of the nanofilter 53 to a front end of the photocatalytic reactor 51. A portion of fluid in the nanofilter 53 may return along the concentrated water collection line 57 to the photocatalytic reactor 51. The concentrated water collection line 57 may be disposed in parallel with the connection line 55. For example, the connection line 55 and the concentrated water collection line 57 may be disposed in parallel with respect to the photocatalytic reactor 51 and the nanofilter 53. A function of the concentrated water collection line 57 will be further discussed in detail below.

FIG. 3 illustrates a cross-sectional view showing a photocatalytic reactor of a recycle filtering device according to some embodiments of the present inventive concepts.

Referring to FIG. 3, the photocatalytic reactor 51 may include an ultraviolet (UV) tank 511 and an ultraviolet (UV) lamp 513. The UV lamp may provide UV light in the UVA range (315 to 400 nm), in the UVB range (290 to 315 nm) or in the UVC range (220 to 290 nm).

The UV tank 511 may provide an ultraviolet (UV) irradiation space 511h. The UV irradiation space 511h may be connected to one or more of the recycle line 23 and the connection line 55. For example, the UV irradiation space 511h may be connected through a reactor inlet 511a to the recycle line 23. In addition, the UV irradiation space 511h may be connected through a reactor outlet 511b to the connection line 55.

The UV lamp 513 may be positioned in the UV irradiation space 511h. The UV lamp 513 may irradiate ultraviolet (UV) light. For example, the UV lamp 513 may irradiate the UV light to fluid passing through the UV irradiation space 511h. The UV light irradiated from the UV lamp 513 may induce a photocatalytic reaction in the fluid. A detailed description thereof will be further discussed below. The UV lamp 513 may be provided in plural. The plurality of UV lamps 513 may be disposed spaced apart from each other in the UV irradiation space 511h. The following will describe a single UV lamp 513.

The concentrated water collection line 57 may be connected to the UV irradiation space 511h. For example, the concentrated water collection line 57 may be connected to the UV irradiation space 511h through the recycle line 23 and the reactor inlet 511a. For another example, the concentrated water collection line 57 may be connected not to the recycle line 23 but to the reactor inlet 511a. For another example, the concentrated water collection line 57 may be connected to the UV irradiation space 511h through a separate inlet (not shown).

FIG. 4 illustrates a cross-sectional view showing a nanofilter of a recycle filtering device according to some embodiments of the present inventive concepts.

Referring to FIG. 4, the nanofilter 53 may include a filtration tank 531 and a nanofiltration membrane 533.

The filtration tank 531 may provide a filtration space 531h. The filtration space 531h may be divided into a first space 531h1 and a second space 531h2. For example, the nanofiltration membrane 533 may divide the filtration space 531h into the first space 531h1 and the second space 531h2. The first space 531h1 may be connected to the connection line 55 and the concentrated water collection line 57. For example, a front end of the first space 531h1 may be connected to the connection line 55. A rear end of the first space 531h1 may be connected to the concentrated water collection line 57. A rear end of the second space 531h2 may be connected to the main tank (see 1 of FIG. 1).

The nanofiltration membrane 533 may be positioned in the filtration space 531h. The nanofiltration membrane 533 may include an acid-resistant substance. For example, the nanofiltration membrane 533 may include XUS1207. The present inventive concepts, however, are not limited thereto, and the nanofiltration membrane 533 may include any other suitable material for filtering foreign substances.

FIG. 5 illustrates a cross-sectional view showing a substrate processing apparatus according to some embodiments of the present inventive concepts.

Referring to FIG. 5, the substrate processing apparatus SA may include a substrate cleaning chamber. For example, the substrate processing apparatus SA may perform a cleaning process on a substrate. The substrate processing apparatus SA may include a cleaning chamber housing 41, a cleaning chuck 43, a rotational driving mechanism 45, a bowl 47, a cleaning nozzle N1, and an outlet 49.

The cleaning chamber housing 41 may provide a cleaning space 41h. The cleaning chuck 43 may be positioned in the cleaning space 41h. The cleaning chuck 43 may support a substrate. The rotational driving mechanism 45 may rotate the cleaning chuck 43. The rotational driving mechanism 45 may rotate the substrate on the cleaning chuck 43. The bowl 47 may surround the cleaning chuck 43. The cleaning nozzle N1 may be upwardly spaced apart from the cleaning chuck 43.

The cleaning nozzle N1 may be connected to the main tank 1. A fluid may be supplied from the main tank 1 through the supply line 21 to the cleaning nozzle N1. The cleaning nozzle N1 may be the inlet of the substrate processing apparatus SA discussed with reference to FIG. 1. The cleaning nozzle N1 may spray fluid to the substrate on the cleaning chuck 43. When the rotational driving mechanism 45 rotates the substrate, the fluid may clean a top surface of the substrate while being pushed toward an outer side of the substrate.

The outlet 49 may be connected to the recycle tank 3. For example, the outlet 49 may be connected through the recycle line 23 to the recycle tank 3. The fluid may be supplied through the cleaning nozzle N1 to the cleaning space 41h, and may be discharged through the outlet 49 to the recycle tank 3. A detailed description thereof will be further discussed below.

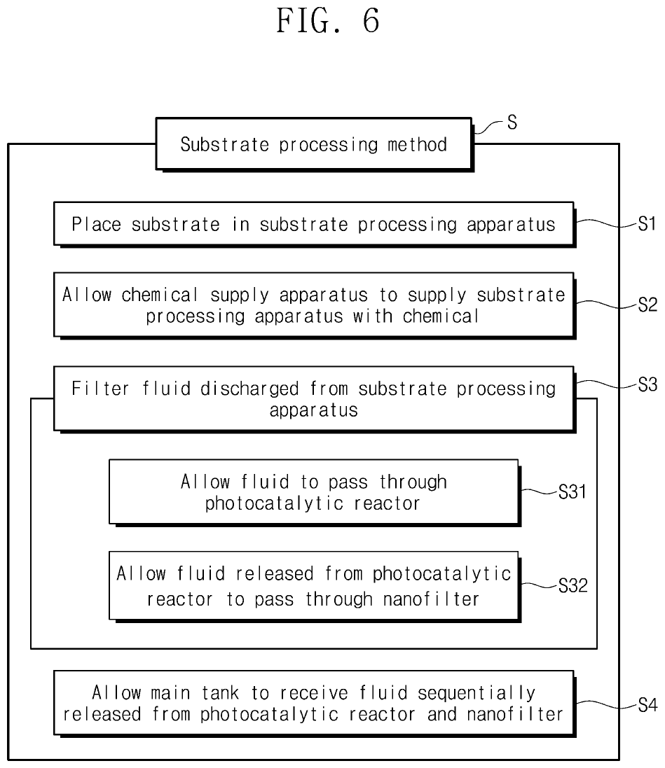

FIG. 6 illustrates a flow chart showing a substrate processing method according to some embodiments of the present inventive concepts.

Referring to FIG. 6, a substrate processing method S may be provided. The substrate processing method S may be a method of processing a substrate by using the semiconductor fabrication system (see MS of FIG. 1) discussed with reference to FIGS. 1 to 5. The substrate processing method S may include placing a substrate into a substrate processing apparatus (S1), allowing a chemical supply apparatus to supply the substrate processing apparatus with chemicals (S2), filtering fluid discharged from the substrate processing apparatus (S3), and allowing a main tank to receive the fluid that has sequentially passed through a photocatalytic reactor and a nanofilter (S4).

The filtration step S3 may include allowing the fluid to pass through the photocatalytic reactor (S31) and allowing the fluid released from the photocatalytic reactor to pass through the nanofilter (S32).

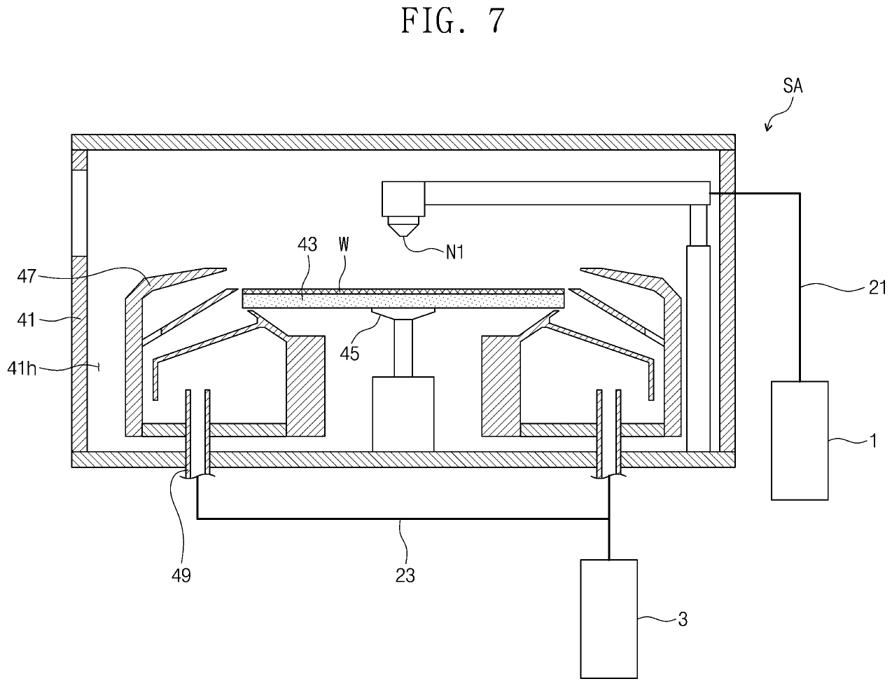

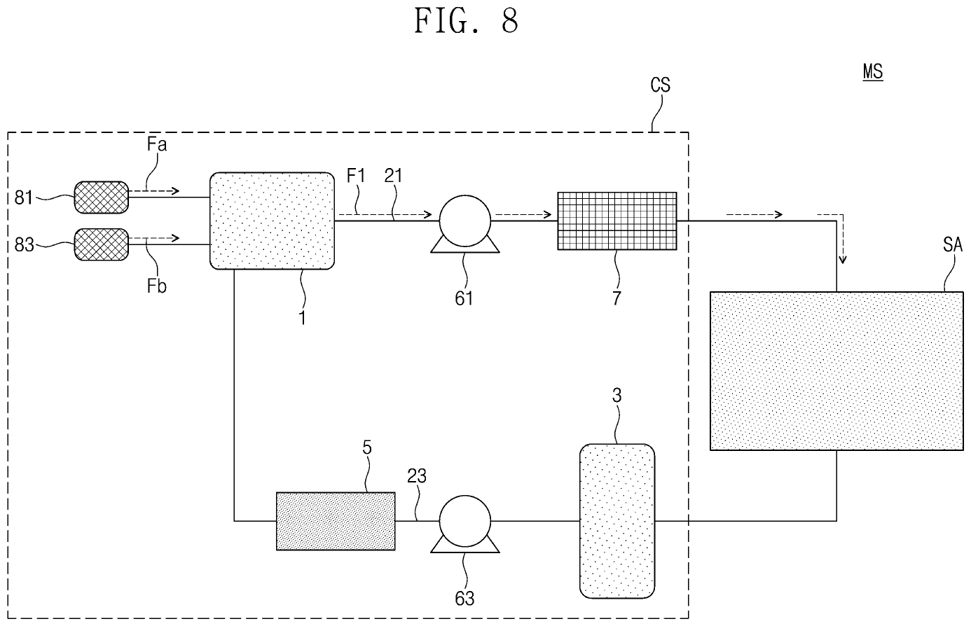

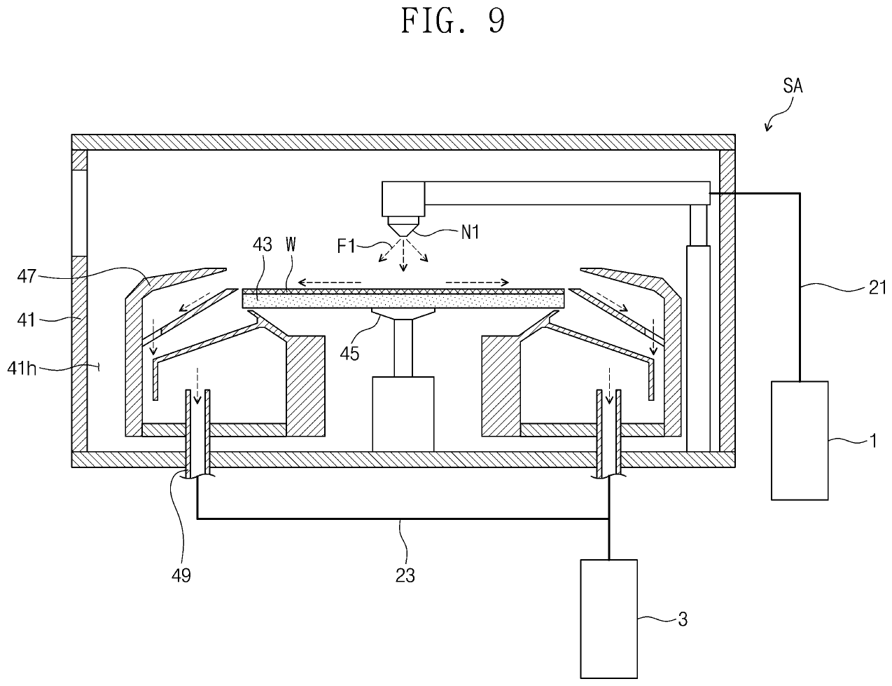

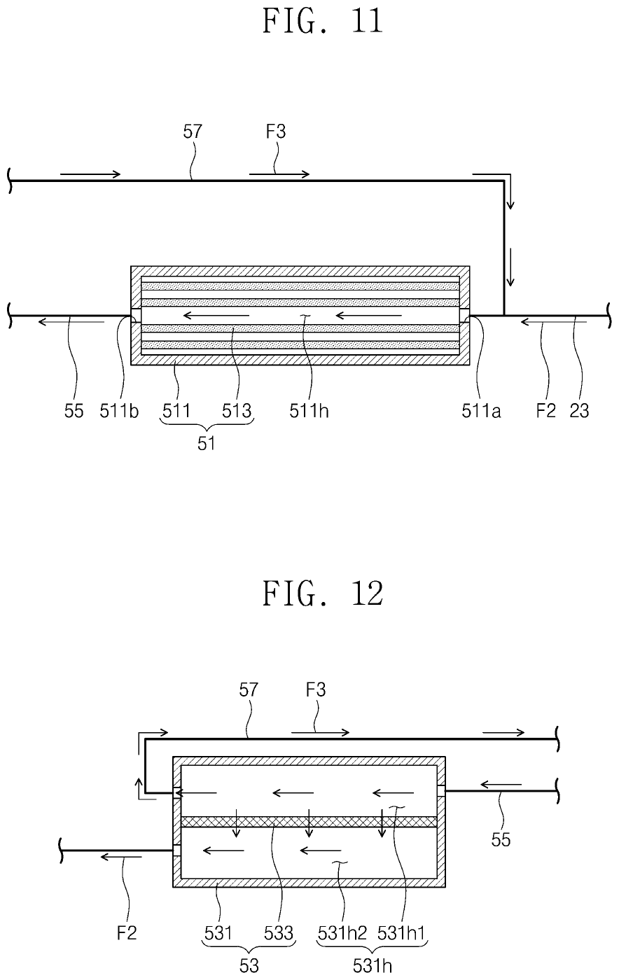

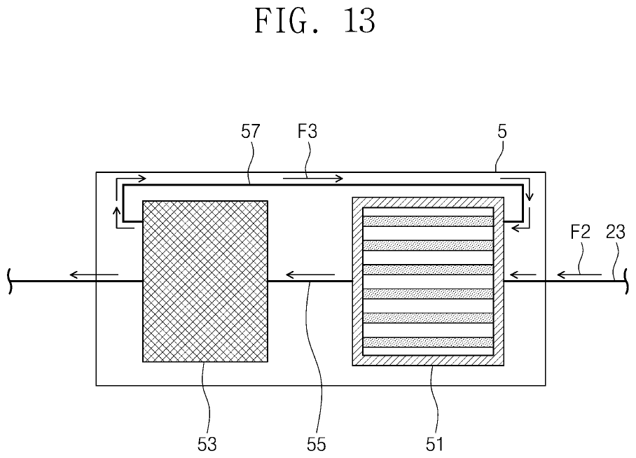

With reference to FIGS. 7 to 13, the following will describe in detail the substrate processing method S of FIG. 6.

FIGS. 7 to 13 illustrate cross-sectional views showing a substrate processing method according to the flow chart of FIG. 6.

Referring to FIGS. 6 and 7, the substrate placement step S1 may include placing a substrate W on the cleaning chuck 43.

Referring to FIGS. 6, 8, and 9, the chemical supply step S2 may include allowing the main tank 1 to supply the substrate processing apparatus SA with a chemical F1. A first fluid Fa may be supplied from the first supply device 81 to the main tank 1. The first fluid Fa may be, for example, deionized water (DIW). In addition, a second fluid Fb may be supplied from the second supply device 83 to the main tank 1. The second fluid Fb may be, for example, diluted sulfuric peroxide (DSP). The first fluid Fa and the second fluid Fb may be mixed in the main tank 1. Thus, a chemical F1 may be formed in the main tank 1. The chemical F1 may include a sulfuric acid. The chemical F1 supplied from the main tank 1 may be introduced through the first filtering device 7 into the substrate processing apparatus SA. For example, the chemical F1 may be sprayed through the cleaning nozzle N1 onto the substrate W. The cleaning chuck 43 may rotate the substrate W, and thus the chemical F1 sprayed onto the substrate W may be pushed toward an outer side of the substrate W. After the substrate W is cleaned, the bowl 47 may collect the chemical F1 pushed toward the outer side of the substrate W. The collected chemical F1 may move through the outlet 49 to the recycle tank 3.

Referring to FIGS. 6, 10, and 11, the fluid passing step S31 may include a fluid F2 discharged from the substrate processing apparatus SA may be introduced through the recycle tank 3 into the photocatalytic reactor 51. When the fluid F2 passes through the UV irradiation space 511h, the UV lamp 513 may irradiate ultraviolet (UV) light to the fluid F2. Thus, a photocatalytic reaction may occur in the fluid F2. The photocatalytic reaction may decompose hydrogen peroxide in the fluid F2. A photocatalyst may be included in the fluid F2 introduced into the UV irradiation space 511h. The photocatalyst may include an iron ion (Fe²⁺) e.g. from iron oxide as a starting material. Catalysts such as titanium oxide, manganese oxide, potassium iodide, potassium permanganate, potassium dichromate, iron chloride, silver, gold, platinum, iron etc. could also be used. The catalyst may be heterogeneous (in a different phase from the fluid being treated) or homogeneous (same phase). Homogeneous catalysts (iodide or iron ions), heterogeneous catalysts (e.g. silver, gold, iron), or enzymes (catalase) may be used to enhance the decomposition of hydrogen peroxide. For example, the fluid F2 discharged after cleaning a substrate in the substrate processing apparatus SA may include a photocatalyst such as an iron ion. When an UV is irradiated to the fluid F2 including the photocatalyst, the photocatalytic reaction may be promoted. Therefore, hydrogen peroxide in the fluid F2 may be decomposed to produce carbon dioxide and water. In addition, the photocatalytic reaction may decompose an organic substance in the fluid F2. The organic substance may be decomposed into carbon dioxide and water.

Referring to FIGS. 6, 10, and 12, the fluid passing step S32 may include introducing the fluid F2 into the filtration space 531h. For example, the fluid F2 introduced along the connection line 55 into the nanofilter 53 may pass through the nanofiltration membrane 533 and move from the first space 531h1 to the second space 531h2. When the fluid F2 passes through the nanofiltration membrane 533, foreign substances in the fluid F2 may be filtered. The fluid F2 filtered while passing through the nanofiltration membrane 533 may return to the main tank 1. When the fluid F2 passes through the first space 531h1, the photocatalyst in the fluid F2 may not pass through the nanofiltration membrane 533. A fluid F3 that does not pass through the nanofiltration membrane 533 may exit from the first space 531h1 without moving to the second space 531h2.

Referring to FIGS. 11, 12, and 13, the fluid (or concentrated water) F3 including the photocatalyst that does not pass through the nanofiltration membrane 533 may move along the concentrated water collection line 57 to the photocatalytic reactor 51. The photocatalyst that is introduced again to the photocatalytic reactor 51 may promote the photocatalytic reaction in the UV irradiation space 511h.

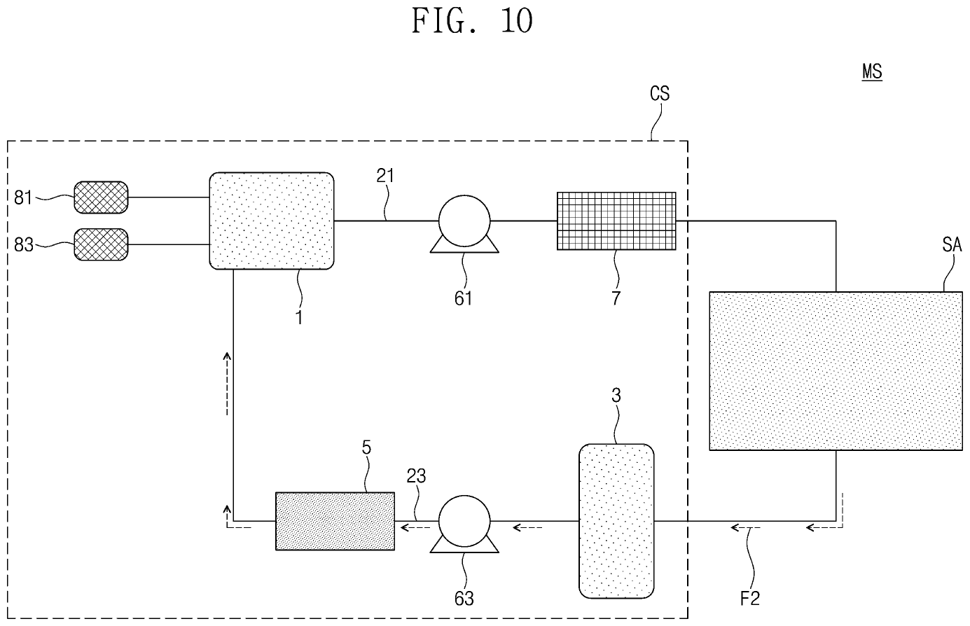

Referring back to FIGS. 6 and 10, the fluid introduction step S4 may include allowing the main tank 1 to receive a fluid that returns after passing through the recycle filtering device 5. The fluid that has passed through the recycle filtering device 5 may include a sulfuric acid. Due to the filtering of the fluid in the recycle filtering device, the fluid released from the recycle filtering device 5 may be introduced into the main tank 1, thereby being reused.

According to a chemical supply apparatus, a semiconductor fabrication system including the same, and a substrate processing method using the same in accordance with some embodiments of the present inventive concepts, a chemical may be reused to reduce discharge of waste water. For example, a sulfuric acid discharged from a substrate processing apparatus may be reused to reduce discharge of the sulfuric acid. Accordingly, it may be possible to protect the environment and to reduce costs.

According to a chemical supply apparatus, a semiconductor fabrication system including the same, and a substrate processing method using the same in accordance with some embodiments of the present inventive concepts, before a fluid reaches a nanofilter, hydrogen peroxide in the fluid may be eliminated in advance in a photocatalytic reactor. It may therefore be possible to prevent damage to a nanofiltration membrane, to increase equipment lifetime, and to reduce costs. In addition, the photocatalytic reactor may be used to eliminate an organic substance in the fluid.

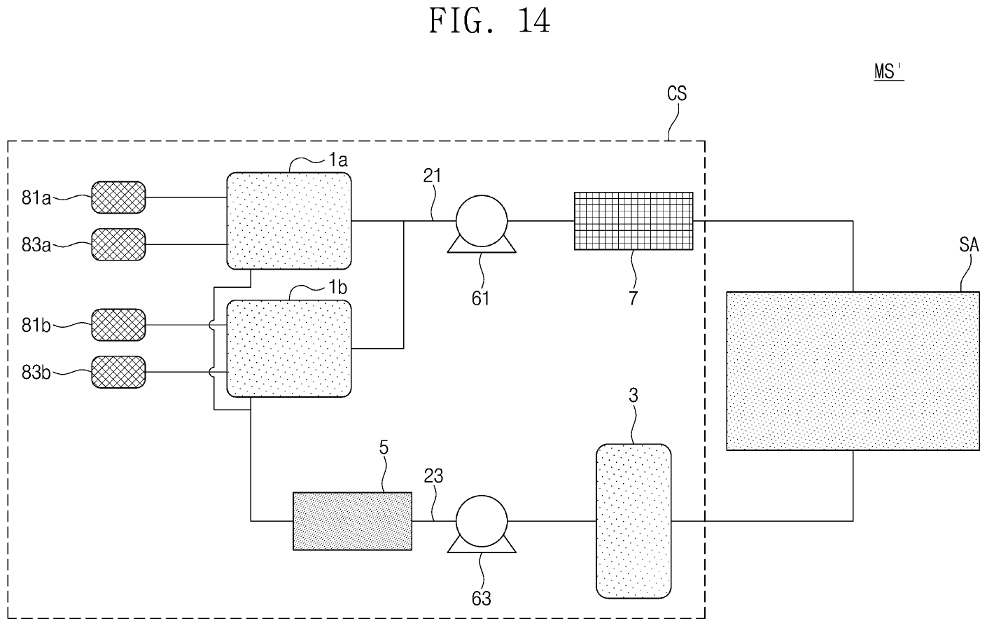

FIG. 14 illustrates a simplified schematic diagram showing a substrate fabrication system according to some embodiments of the present inventive concepts.

The following will omit a description substantially the same as or similar to that with reference to FIGS. 1 to 13.

Referring to FIG. 14, a semiconductor fabrication system MS' may be provided. The semiconductor fabrication system MS' may include a substrate processing apparatus SA and a chemical supply apparatus CS. The chemical supply apparatus CS may include a first main tank 1a, a second main tank 1b, a supply line 21, a first filtering device 7, a main pump 61, a recycle tank 3, a recycle line 23, a recycle filtering device 5, a recycle pump 63, a first supply device 81a, a second supply device 83a, a third supply device 81b, and a fourth supply device 83b. Differently from that discussed in FIG. 1, two main tanks 1a and 1b may be provided. The recycle line 23 may be connected to each of the first main tank 1a and the second main tank 1b.

According to a chemical supply apparatus, a semiconductor fabrication system including the same, and a substrate processing method using the same of the present inventive concepts, it may be possible to reuse chemicals.

According to a chemical supply apparatus, a semiconductor fabrication system including the same, and a substrate processing method using the same of the present inventive concepts, it may be possible to reduce discharge of waste water.

According to a chemical supply apparatus, a semiconductor fabrication system including the same, and a substrate processing method using the same of the present inventive concepts, it may be possible to prevent damage to a nanofiltration membrane.

Effects of the present inventive concepts are not limited to the mentioned above, other effects which have not been mentioned above will be clearly understood to those skilled in the art from the following description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A semiconductor fabrication system, comprising:
a substrate processing apparatus; and
a chemical supply apparatus that supplies the substrate processing apparatus with a chemical,
wherein the chemical supply apparatus includes:
a main tank;
a supply line that connects the main tank to an inlet of the substrate processing apparatus;
a recycle tank connected to an outlet of the substrate processing apparatus; and
a recycle filtering device between the recycle tank and the main tank,
wherein the recycle filtering device includes:
a photocatalytic reactor;
a nanofilter between the photocatalytic reactor and the main tank; and
a connection line that connects the photocatalytic reactor to the nanofilter.

2. The semiconductor fabrication system of claim 1, wherein the recycle filtering device further includes a concentrated water collection line that connects a rear end of the nanofilter to a front end of the photocatalytic reactor,
wherein the concentrated water collection line is in parallel with the connection line.

3. The semiconductor fabrication system of claim 2, wherein the nanofilter includes:
a filtration tank that provides a filtration space; and
a nanofiltration membrane in the filtration space,
wherein the nanofiltration membrane divides the filtration space into a first space and a second space,
wherein the first space is connected to each of the connection line and the concentrated water collection line, and
wherein the second space is connected to the main tank.

4. The semiconductor fabrication system of claim 3, wherein the nanofiltration membrane includes an acid-resistant substance.

5. The semiconductor fabrication system of claim 1, wherein the photocatalytic reactor includes:
an ultraviolet (UV) tank that provides an ultraviolet (UV) irradiation space; and
an ultraviolet (UV) lamp in the UV irradiation space.

6. The semiconductor fabrication system of claim 1, wherein the chemical supply apparatus further includes a first filtering device between the main tank and the substrate processing apparatus.

7. The semiconductor fabrication system of claim 1, wherein the chemical supply apparatus further includes a recycle pump between the recycle tank and the recycle filtering device.

8. The semiconductor fabrication system of claim 1, wherein the substrate processing apparatus includes a substrate cleaning chamber.

9. The semiconductor fabrication system of claim 8, wherein the substrate cleaning chamber includes:
a cleaning chamber housing that provides a cleaning space;
a cleaning chuck in the cleaning space; and
a cleaning nozzle in the cleaning space and upwardly spaced apart from the cleaning chuck.

10. The semiconductor fabrication system of claim 9, wherein
the inlet of the substrate processing apparatus is the cleaning nozzle, and
the outlet of the substrate processing apparatus is formed in the substrate cleaning chamber.

11. A chemical supply apparatus, comprising:
a main tank that temporarily stores fluid;
a supply line connected to the main tank to allow a substrate processing apparatus to receive the fluid stored in the main tank;
a recycle line connected to the main tank to allow the main tank to receive the fluid discharged from the substrate processing apparatus;
a recycle tank on the recycle line; and
a recycle filtering device between the recycle tank and the main tank,
wherein the recycle filtering device includes:
a photocatalytic reactor that has an ultraviolet (UV) lamp;
a nanofilter between the photocatalytic reactor and the main tank;
a connection line that connects the photocatalytic reactor to the nanofilter; and
a concentrated water collection line that connects the nanofilter to the photocatalytic reactor,
wherein the concentrated water collection line is in parallel with the connection line.

12. The chemical supply apparatus of claim 11, wherein the nanofilter includes:
a filtration tank that provides a filtration space; and
a nanofiltration membrane in the filtration space,
wherein the nanofiltration membrane divides the filtration space into a first space and a second space,
wherein the first space is connected to each of the connection line and the concentrated water collection line, and
wherein the second space is connected to the main tank.

13. The chemical supply apparatus of claim 12, wherein the nanofiltration membrane includes an acid-resistant substance.

14. The chemical supply apparatus of claim 11, further comprising a first filtering device between the main tank and the substrate processing apparatus.

15. A substrate processing method, comprising:
placing a substrate in a substrate processing apparatus;
allowing a chemical supply apparatus to supply a chemical to the substrate processing apparatus in which the substrate is placed; and
filtering fluid discharged from the substrate processing apparatus,
wherein the chemical supply apparatus includes:
a main tank;
a supply line that connects the main tank to an inlet of the substrate processing apparatus; and
a recycle filtering device connected to an outlet of the substrate processing apparatus,
wherein the recycle filtering device includes:
a photocatalytic reactor; and
a nanofilter connected to the photocatalytic reactor,
wherein filtering the fluid includes:
allowing the fluid discharged from the substrate processing apparatus to pass through the photocatalytic reactor; and
allowing the fluid released from the photocatalytic reactor to pass through the nanofilter.

16. The substrate processing method of claim 15, wherein filtering the fluid further includes allowing the main tank to receive the fluid that is sequentially released from the photocatalytic reactor and the nanofilter.

17. The substrate processing method of claim 15, wherein the photocatalytic reactor includes:
an ultraviolet (UV) tank that provides an ultraviolet (UV) irradiation space; and
an ultraviolet (UV) lamp in the UV irradiation space,
wherein allowing the fluid to pass through the photocatalytic reactor includes allowing the fluid to pass through the UV irradiation space.

18. The substrate processing method of claim 15, wherein the recycle filtering device further includes:
a connection line that connects the photocatalytic reactor to the nanofilter; and
a concentrated water collection line that connects a rear end of the nanofilter to a front end of the photocatalytic reactor and is in parallel with the connection line,
wherein the nanofilter includes:
a filtration tank that provides a filtration space; and
a nanofiltration membrane in the filtration space,
wherein the nanofiltration membrane divides the filtration space into a first space and a second space,
wherein the first space is connected to each of the connection line and the concentrated water collection line, and
wherein the second space is connected to the main tank.

19. The substrate processing method of claim 18, wherein allowing the fluid to pass through the nanofilter includes:
filtering the fluid while passing through the nanofiltration membrane, the fluid being introduced from the photocatalytic reactor along the connection line to the first space; and
allowing concentrated water in the first space to move along the concentrated water collection line to the photocatalytic reactor.

20. The substrate processing method of claim 15, wherein the chemical supplied from the chemical supply apparatus to the substrate processing apparatus includes a sulfuric acid (H₂SO₄).
